(19) United States
(12) Patent Application Publication
(10) Pub. No.: US 2020/0168834 A1
(43) Pub. Date: May 28, 2020

(54) ORGANIC LIGHT EMITTING DIODE ELEMENT AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Yifei BING, Shenzhen, Guangdong (CN); Tsungyuan WU, Shenzhen, Guangdong (CN); Xiaoling WU, Shenzhen, Guangdong (CN)

(21) Appl. No.: 16/088,689

(22) PCT Filed: Sep. 6, 2018
(86) PCT No.: PCT/CN2018/104449

§ 371 Date: Sep. 26, 2018

(30) Foreign Application Priority Data
Mar. 20, 2018 (CN) 201810232019.7

(51) Int. Cl. H01L 51/52; H01L 51/56; H01L 27/32

(52) U.S. Cl. CPC H01L 51/5228; H01L 27/326; H01L 51/56; H01L 51/5212

(57) ABSTRACT

The present invention provides an OLED element and a manufacture method thereof. A cathode contact layer spaced from the anode layer is provided on the substrate of the organic light emitting diode element. The cathode layer contacts the cathode contact layer through the cathode contact hole in the pixel definition layer. As the organic light emitting diode element works, the same negative voltage is applied to the cathode layer and the cathode contact layer. The cathode contact layer can directly provide voltage and current compensations to the cathode layer, thus to prevent uneven brightness due to IR Drop appearing to a large scale organic light emitting diode display panel. The manufacturing method of the organic light emitting diode element can effectively prevent IR Drop for the organic light emitting diode element and can further improve an uneven brightness of an organic light emitting diode display panel.

### FIELD OF THE INVENTION

The present invention relates to a display technology field, and more particularly to an organic light emitting diode element and a manufacturing method thereof.

### BACKGROUND OF THE INVENTION

Organic Light Emitting Diodes (OLEDs) belong to a novel current type semiconductor light emitting element, which is an autonomous light emitting technology by controlling the injection of the carriers of the element and by recombining and exciting the organic material to emit light for display. Compared with a passively-illuminated liquid crystal display (LCD), the self-luminous OLED display possesses the advantages of fast response, high contrast, wide viewing angle, etc., and is easy to achieve flexible display to be favored in the industry. The industry agrees that OLED display is likely to become the mainstream of the next generation display technology.

The active matrix organic light emitting diode (AMOLED) and the LCD display panels basically have the same display principle and both realize the display by controlling the thin film transistor (TFT) of each sub pixel. The difference between the two is that the AMOLED display controls the current of the OLED with the TFT to change the light emission brightness; the LCD display adjusts the transmittance of the backlight by controlling the voltage applied across the liquid crystal cell with the TFT. As comparing the current driving ability of TFTs for the two, the requirement for the AMOLED display is higher. OLEDs are very sensitive to the driving current. A weak current variation will affect the luminous intensity. Therefore, TFTs are required to constantly and steadily provide the operating current. This imposes stringent requirements on the stability of the AMOLED driving circuit, which also to have a higher standard for the design goals of the AMOLED driving circuit.

At room temperature, the metal conductor resistance is non-zero, and the current through the conductor will produce a certain voltage drop. This phenomenon is called IR Drop. The IR Drops on metal wires can cause potential differences at different locations from the input end. On a large scale display panel, such IR Drops will cause differences in the currents of the OLEDs at different positions, resulting in non-uniform light emission of the panel and affecting the image display quality.

### SUMMARY OF THE INVENTION

An objective of the present invention is to provide an organic light emitting diode element, which can effectively prevent IR Drop for the organic light emitting diode element and can further improve an uneven brightness of an organic light emitting diode display panel.

Another objective of the present invention is to provide a manufacturing method of an organic light emitting diode element, which can effectively prevent IR Drop for the organic light emitting diode element and can further improve an uneven brightness of an organic light emitting diode display panel.

For realizing the aforesaid objective, the present invention provides an organic light emitting diode element, comprising a substrate, an anode layer and a cathode contact layer, which are arranged on the substrate and spaced from each other, a pixel definition layer arranged substrate, the anode layer and the cathode contact layer, an organic light emitting layer arranged on the anode layer, and a cathode layer arranged on the pixel definition layer and the organic light emitting layer;

wherein the pixel definition layer is correspondingly provided with a cathode contact hole on the cathode contact layer;

the cathode layer covers the cathode contact layer and contacts the cathode contact layer through the cathode contact hole.

The anode layer and the cathode contact layer are spaced from each other with 10 μm to 20 μm.

The pixel definition layer encloses a pixel opening on the anode layer, and the organic light emitting layer is arranged in the pixel opening.

The cathode contact layer is spaced from the anode layer and the organic light emitting layer at the same time with the pixel definition layer;

a material of the anode layer and the cathode contact layer is a hydrophilic conductive material, and a material of the pixel definition layer is a hydrophobic material.

The organic light emitting layer comprises a hole injection layer, a hole transport layer, a light emitting layer and an electron transport layer, which are sequentially arranged on the anode layer from bottom to top.

The present invention further provides a manufacturing method of an organic light emitting diode element, comprising steps of:

Step S1, providing a substrate, and forming an anode layer and a cathode contact layer, which are arranged on the substrate and spaced from each other;

Step S2, forming a pixel definition layer on the substrate, the anode layer and the cathode contact layer, wherein the pixel definition layer is correspondingly provided with a cathode contact hole on the cathode contact layer;

Step S3, forming an organic light emitting layer on the anode layer, and forming a cathode layer on the pixel definition layer and the organic light emitting layer, wherein the cathode layer covers the cathode contact layer and contacts the cathode contact layer through the cathode contact hole.

In Step S1, the anode layer and the cathode contact layer are spaced from each other with 10 μm to 20 μm.

In Step S2, the pixel definition layer encloses a pixel opening on the anode layer;

in Step S3, the organic light emitting layer is arranged in the pixel opening.

The cathode contact layer is spaced from the anode layer and the organic light emitting layer at the same time with the pixel definition layer;

a material of the anode layer and the cathode contact layer is a hydrophilic conductive material, and a material of the pixel definition layer is a hydrophobic material.

In Step S3, the organic light emitting layer comprises a hole injection layer, a hole transport layer, a light emitting layer and an electron transport layer, which are sequentially arranged on the anode layer from bottom to top.

The present invention further provides an organic light emitting diode element, comprising a substrate, an anode layer and a cathode contact layer, which are arranged on the substrate and spaced from each other, a pixel definition layer arranged substrate, the anode layer and the cathode contact layer, an organic light emitting layer arranged on the anode layer, and a cathode layer arranged on the pixel definition layer and the organic light emitting layer;

wherein the pixel definition layer is correspondingly provided with a cathode contact hole on the cathode contact layer;

the cathode layer covers the cathode contact layer and contacts the cathode contact layer through the cathode contact hole;

wherein the anode layer and the cathode contact layer are spaced from each other with 10 μm to 20 μm;

wherein the pixel definition layer encloses a pixel opening on the anode layer, and the organic light emitting layer is arranged in the pixel opening;

wherein the cathode contact layer is spaced from the anode layer and the organic light emitting layer at the same time with the pixel definition layer;

a material of the anode layer and the cathode contact layer is a hydrophilic conductive material, and a material of the pixel definition layer is a hydrophobic material;

wherein the organic light emitting layer comprises a hole injection layer, a hole transport layer, a light emitting layer and an electron transport layer, which are sequentially arranged on the anode layer from bottom to top.

The benefits of the present invention are: provided is an organic light emitting diode element. A cathode contact layer spaced from the anode layer is provided on the substrate of the organic light emitting diode element. The cathode layer contacts the cathode contact layer through the cathode contact hole in the pixel definition layer. As the organic light emitting diode element works, the same negative voltage is applied to the cathode layer and the cathode contact layer. The cathode contact layer can directly provide voltage and current compensations to the cathode layer, thus to prevent uneven brightness due to IR Drop appearing to a large scale organic light emitting diode display panel. The present invention provides a manufacturing method of an organic light emitting diode element. A cathode contact layer spaced from the anode layer is provided on the substrate of the organic light emitting diode element. A pixel definition layer is correspondingly provided with a cathode contact hole on the cathode contact layer. Thus, the cathode layer contacts the cathode contact layer through the cathode contact hole in the pixel definition layer. As the organic light emitting diode element works, the same negative voltage is applied to the cathode layer and the cathode contact layer. The cathode contact layer can directly provide voltage and current compensations to the cathode layer, thus to prevent uneven brightness due to IR Drop appearing to a large scale organic light emitting diode display panel.

In order to better understand the characteristics and technical aspect of the invention, please refer to the following detailed description and accompanying drawings of the present invention. However, the drawings are provided for reference only and are not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a diagram of an organic light emitting diode element of the present invention;

FIG. 2 is a flowchart of a manufacturing method of an organic light emitting diode element according to the present invention;

FIG. 3 is a diagram of Step 1 of a manufacturing method of an organic light emitting diode element according to the present invention;

FIG. 4 is a diagram of Step 2 of a manufacturing method of an organic light emitting diode element according to the present invention;

FIG. 5 is a diagram of Step 3 of a manufacturing method of an organic light emitting diode element according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

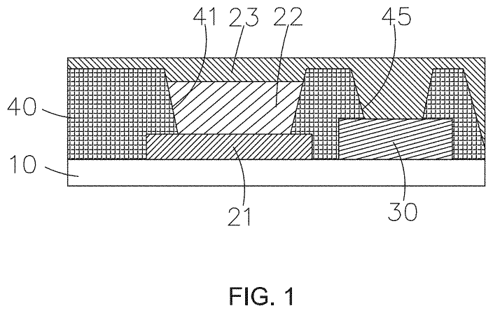

Please refer to FIG. 1. The present invention first provides an organic light emitting diode element, comprising a substrate 10, an anode layer 21 and a cathode contact layer 30, which are arranged on the substrate 10 and spaced from each other, a pixel definition layer 40 arranged substrate 10, the anode layer 21 and the cathode contact layer 30, an organic light emitting layer 22 arranged on the anode layer 21, and a cathode layer 23 arranged on the pixel definition layer 40 and the organic light emitting layer 22.

The pixel definition layer 40 is correspondingly provided with a cathode contact hole 45 on the cathode contact layer 30.

The cathode layer 23 covers the cathode contact layer 30 and contacts the cathode contact layer 30 through the cathode contact hole 45.

Specifically, the substrate 10 is a glass substrate.

Specifically, the anode layer 21 and the cathode contact layer 30 are spaced from each other with 10 μm to 20 μm.

Specifically, the pixel definition layer 40 encloses a pixel opening 41 on the anode layer 21, and the organic light emitting layer 22 is arranged in the pixel opening 41.

Specifically, the cathode contact layer 30 is spaced from the anode layer 21 and the organic light emitting layer 22 at the same time with the pixel definition layer 40.

Specifically, the cathode layer 23 is higher than the pixel defining layer 40 and is not separated by the pixel opening 41 of the pixel definition layer 40. In the cathode layer 23, the top of the pixel opening 41 of the pixel definition layer 40 and the top of the cathode contact hole 45 are connected. The cathode layer is an entire surface structure.

Specifically, a material of the anode layer 21 and the cathode contact layer 30 is a hydrophilic conductive material, and a material of the pixel definition layer 40 is a hydrophobic material.

Specifically, the organic light emitting layer 22 comprises a hole injection layer (HIL), a hole transport layer (HTL), a light emitting layer (EML) and an electron transport layer (ETL), which are sequentially arranged on the anode layer 21 from bottom to top.

A cathode contact layer 30 spaced from the anode layer 21 is provided on the substrate 10 of the organic light emitting diode element of the present invention. The cathode layer 23 contacts the cathode contact layer 30 through the cathode contact hole 45 in the pixel definition layer 40. As the organic light emitting diode element is applied in an OLED display panel and works, a positive voltage is applied to the anode layer 21 and the same negative voltage is respectively applied to the cathode layer 23 and the cathode contact layer 30. The cathode contact layer 30 can directly provide voltage and current compensations to the cathode layer 23. Since the OLED element of each pixel is provided with the cathode contact layer 30 in contact with the cathode layer 23, thus preventing uneven brightness due to IR Drop appearing to a large scale organic light emitting diode display panel.

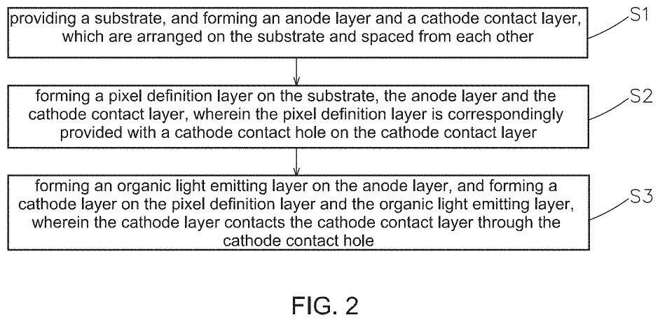

Please refer to FIG. 2. On the basis of the aforesaid OLED element, the present invention further provides a manufacturing method of an organic light emitting diode element, comprising steps of:

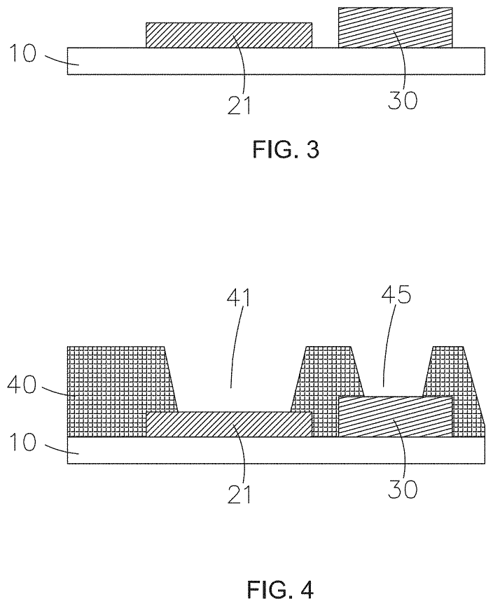

Step S1, as shown in FIG. 3, providing a substrate 10, and forming an anode layer 21 and a cathode contact layer 30, which are arranged on the substrate 10 and spaced from each other.

Specifically, the substrate 10 is a glass substrate.

Specifically, in Step S1, the anode layer 21 and the cathode contact layer 30 are spaced from each other with 10 μm to 20 μm and are not connected to each other.

Specifically, a material of the anode layer 21 and the cathode contact layer 30 is a hydrophilic conductive material.

Step S2, as shown in FIG. 4, forming a pixel definition layer 40 on the substrate 10, the anode layer 21 and the cathode contact layer 30. The pixel definition layer 40 encloses a pixel opening 41 on the anode layer 21. The pixel definition layer 40 is correspondingly provided with a cathode contact hole 45 on the cathode contact layer 30.

Specifically, a material of the pixel definition layer 40 is a hydrophobic material.

Specifically, the cathode contact layer 30 is spaced from the anode layer 21 with the pixel definition layer 40. Meanwhile, the cathode contact layer 30 is spaced from the organic light emitting layer 22, which is subsequently formed, at the same time with the pixel definition layer 40.

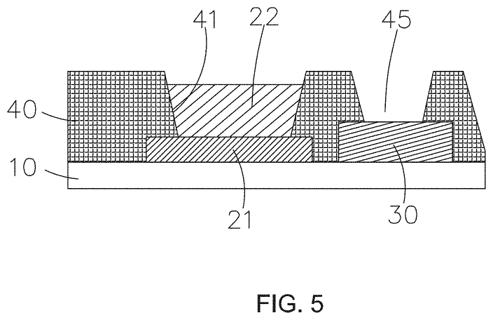

Step S3, as shown in FIG. 5, forming an organic light emitting layer 22 on the anode layer 21 in the pixel opening 41 of the pixel definition layer 40, and forming a cathode layer 23 on the pixel definition layer 40 and the organic light emitting layer 22. The cathode layer 23 covers the cathode contact layer 30 and contacts the cathode contact layer 30 through the cathode contact hole 45 to obtain an OLED element structure shown in FIG. 1.

Specifically, the cathode layer 23 is higher than the pixel defining layer 40 and is not separated by the pixel opening 41 of the pixel definition layer 40. In the cathode layer 23, the top of the pixel opening 41 of the pixel definition layer 40 and the top of the cathode contact hole 45 are connected. The cathode layer is an entire surface structure.

Specifically, the organic light emitting layer 22 comprises a hole injection layer, a hole transport layer, a light emitting layer and an electron transport layer, which are sequentially arranged on the anode layer 21 from bottom to top.

In the manufacturing method of the OLED element according to the present invention, a cathode contact layer 30 spaced from the anode layer 21 is provided on the substrate 10. The pixel definition layer 40 is correspondingly provided with a cathode contact hole 45 on the cathode contact layer 30. Thus, the cathode layer 23 contacts the cathode contact layer 30 through the cathode contact hole 45 in the pixel definition layer 40. As the organic light emitting diode element is applied in an OLED display panel and works, a positive voltage is applied to the anode layer 21 and the same negative voltage is applied to the cathode layer 23 and the cathode contact layer 30, respectively. The cathode contact layer 30 can directly provide voltage and current compensations to the cathode layer 23. Since the OLED element of each pixel is provided with the cathode contact layer 30 in contact with the cathode layer 23, thus preventing uneven brightness due to IR Drop appearing to a large scale organic light emitting diode display panel.

In conclusion, provided is an organic light emitting diode element. A cathode contact layer spaced from the anode layer is provided on the substrate of the organic light emitting diode element. The cathode layer contacts the cathode contact layer through the cathode contact hole in the pixel definition layer. As the organic light emitting diode element works, the same negative voltage is applied to the cathode layer and the cathode contact layer, respectively. The cathode contact layer can directly provide voltage and current compensations to the cathode layer, thus to prevent uneven brightness due to IR Drop appearing to a large scale organic light emitting diode display panel. The present invention provides a manufacturing method of an organic light emitting diode element. A cathode contact layer spaced from the anode layer is provided on the substrate of the organic light emitting diode element. A pixel definition layer is correspondingly provided with a cathode contact hole on the cathode contact layer. Thus, the cathode layer contacts the cathode contact layer through the cathode contact hole in the pixel definition layer. As the organic light emitting diode element works, the same negative voltage is applied to the cathode layer and the cathode contact layer, respectively. The cathode contact layer can directly provide voltage and current compensations to the cathode layer, thus to prevent uneven brightness due to IR Drop appearing to a large scale organic light emitting diode display panel.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. An organic light emitting diode element, comprising a substrate, an anode layer and a cathode contact layer, which are arranged on the substrate and spaced from each other, a pixel definition layer arranged substrate, the anode layer and the cathode contact layer, an organic light emitting layer arranged on the anode layer, and a cathode layer arranged on the pixel definition layer and the organic light emitting layer;
wherein the pixel definition layer is correspondingly provided with a cathode contact hole on the cathode contact layer;
the cathode layer covers the cathode contact layer and contacts the cathode contact layer through the cathode contact hole.

2. The organic light emitting diode element according to claim 1, wherein the anode layer and the cathode contact layer are spaced from each other with 10 μm to 20 μm.

3. The organic light emitting diode element according to claim 1, wherein the pixel definition layer encloses a pixel opening on the anode layer, and the organic light emitting layer is arranged in the pixel opening.

4. The organic light emitting diode element according to claim 1, wherein the cathode contact layer is spaced from the anode layer and the organic light emitting layer at the same time with the pixel definition layer;
a material of the anode layer and the cathode contact layer is a hydrophilic conductive material, and a material of the pixel definition layer is a hydrophobic material.

5. The organic light emitting diode element according to claim 1, wherein the organic light emitting layer comprises a hole injection layer, a hole transport layer, a light emitting layer and an electron transport layer, which are sequentially arranged on the anode layer from bottom to top.

6. A manufacturing method of an organic light emitting diode element, comprising steps of:
Step S1, providing a substrate, and forming an anode layer and a cathode contact layer, which are arranged on the substrate and spaced from each other;
Step S2, forming a pixel definition layer on the substrate, the anode layer and the cathode contact layer, wherein the pixel definition layer is correspondingly provided with a cathode contact hole on the cathode contact layer;
Step S3, forming an organic light emitting layer on the anode layer, and forming a cathode layer on the pixel definition layer and the organic light emitting layer, wherein the cathode layer covers the cathode contact layer and contacts the cathode contact layer through the cathode contact hole.

7. The manufacturing method of the organic light emitting diode element according to claim 6, wherein in Step S1, the anode layer and the cathode contact layer are spaced from each other with 10 μm to 20 μm.

8. The manufacturing method of the organic light emitting diode element according to claim 6, wherein in Step S2, the pixel definition layer encloses a pixel opening on the anode layer;
in Step S3, the organic light emitting layer is arranged in the pixel opening.

9. The manufacturing method of the organic light emitting diode element according to claim 6, wherein the cathode contact layer is spaced from the anode layer and the organic light emitting layer at the same time with the pixel definition layer;
a material of the anode layer and the cathode contact layer is a hydrophilic conductive material, and a material of the pixel definition layer is a hydrophobic material.

10. The manufacturing method of the organic light emitting diode element according to claim 6, wherein in Step S3, the organic light emitting layer comprises a hole injection layer, a hole transport layer, a light emitting layer and an electron transport layer, which are sequentially arranged on the anode layer from bottom to top.

11. An organic light emitting diode element, comprising a substrate, an anode layer and a cathode contact layer, which are arranged on the substrate and spaced from each other, a pixel definition layer arranged substrate, the anode layer and the cathode contact layer, an organic light emitting layer arranged on the anode layer, and a cathode layer arranged on the pixel definition layer and the organic light emitting layer;
wherein the pixel definition layer is correspondingly provided with a cathode contact hole on the cathode contact layer;
the cathode layer covers the cathode contact layer and contacts the cathode contact layer through the cathode contact hole;
wherein the anode layer and the cathode contact layer are spaced from each other with 10 μm to 20 μm;
wherein the pixel definition layer encloses a pixel opening on the anode layer, and the organic light emitting layer is arranged in the pixel opening;
wherein the cathode contact layer is spaced from the anode layer and the organic light emitting layer at the same time with the pixel definition layer;
a material of the anode layer and the cathode contact layer is a hydrophilic conductive material, and a material of the pixel definition layer is a hydrophobic material;
wherein the organic light emitting layer comprises a hole injection layer, a hole transport layer, a light emitting layer and an electron transport layer, which are sequentially arranged on the anode layer from bottom to top.
